(19) United States
(12) Patent Application Publication
(10) Pub. No.: US 2006/0138579 A1
(43) Pub. Date: Jun. 29, 2006

(54) Image sensor package, solid state imaging device, and fabrication methods thereof

(75) Inventors: Kyu-ho Shin, Seoul (KR); Chang-youl Moon, Suwon-si (KR); Arthur Darbinian, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/282,045

(22) Filed: Nov. 18, 2005

(30) Foreign Application Priority Data
Dec. 23, 2004 (KR) 2004-111255

(51) Int. Cl. H01L 31/0203

(52) U.S. Cl. 257/433

(57) ABSTRACT

An image sensor package and a solid state imaging device. The image sensor package includes an image sensor having an image sensor and connection pads on a wafer. A transparent plate is attached to the upper surface of the image sensor chip via an adhesive. The connection pads include connectors, and the image sensor package exchanges signals with a main board of the solid image device through the connectors.

### CROSS-REFERENCE TO RELATED APPLICATIONS

This application claims the benefit of Korean Patent Application No. 2004-111255 filed Dec. 23, 2004, in the Korean Intellectual Property Office, the disclosure of which is incorporated herein by reference.

### BACKGROUND OF THE INVENTION

1. Field of the Invention

The present invention relates to a semiconductor package; and, more particularly, to an image sensor package, a solid state imaging device, and fabrication methods thereof.

2. Description of the Related Art

A semiconductor device fabricated on a wafer, e.g., a chip is fragile and therefore, cannot be directly handled by a user as an electric device. Thus, packaging is required to use the semiconductor device as well as to protect the same. The semiconductor device fabricated on a wafer is completed by packaging in a semiconductor package.

An image sensor package is used as a semiconductor package for solid state imaging in applications such as a video camera, a digital camera, a camera phone, a photocopier, an image scanner and the like.

Referring to FIG. 1, a common image sensor package 10 is fabricated by attaching an image sensor chip 2 to a substrate 1 with a circuit pattern formed thereon using an adhesive 3 such as an epoxy, and by attaching bonding wire 4 for exchanging signals between a chip pad on the image sensor chip 2 and the substrate 1. Transparent glass or a glass module 5 in module form is placed on top of the image sensor chip 2 to protect the image sensor chip 2 and the wire 4. At the bottom of the substrate 1, a plurality of solder balls 6 are attached. The solder balls 6 are housed in a main board (not shown) of a solid state imaging device. Meanwhile, via holes 7 formed inside the substrate 1 exchange signals with the solder balls 6, and the via holes 7 are filled with a conductive material.

In the image sensor packet 10 having the above structure, image signals of light passing through the glass 5 are transformed into electrical signals in the image sensor chip 2, and the electrical signals are transmitted to the substrate 1 through the wire 4 and to the main board (not shown) through the solder balls 6 of the substrate 1.

Since a conventional image sensor package uses a wire bonding method to electrically connect the image sensor chip and the substrate, the size and thickness of the entire package becomes thick due to the loop height of the wire, and the production cost is increased as well. Also, since the glass or the glass module is attached to each image sensor chip, the entire size of the image sensor package becomes large and the production cost is increased.

Therefore, a recent research trend is the development of a Chip-Size Package (CSP) using direct chip attachment (DCA), in which an imaging chip is directly attached to the substrate without wire bonding so as to make the image sensor package small and thin, and a Wafer-Level Package (WLP) in which the packaging is carried out on a wafer to reduce the number of fabrication processes.

### SUMMARY OF THE INVENTION

It is therefore an object of the present invention to provide a small and thin image sensor package through reduced fabrication processing steps, a solid state imaging device, and fabrication methods thereof.

In accordance with a first aspect, the present invention provides an image sensor package which includes: an image sensor chip having an image sensor and a connection pad; a transparent plate attached to the image sensor chip via an adhesive; and a connector, one side of which is connected to the connection pad and the other side of which is connected to a main board, wherein the image sensor package is electrically connected to a main board of a solid image device for exchange of signals.

Preferably, the connector comprises any of a bump, an anisotropic conductive film (ACF), anisotropic conductive paste (ACP), and a screen printing.

Also preferably, the bump is a solder bump or a gold (Au) bump.

Also preferably, the connection pad is formed of gold having high electrical conductivity.

In accordance with another aspect, the present invention provides a solid state imaging device, which includes: a main board; an image sensor chip having an image sensor and a connection pad; a transparent plate attached to the image sensor chip via an adhesive; a connector one side of which is connected to the connection pad and the other side of which is connected to the main board; and a lens housing mounted on a side of the main board opposite the connector.

Preferably, the main board is a rigid printed circuit board or a flexible printed circuit board.

In accordance with another aspect, the present invention provides a method for fabricating an image sensor package, which includes the steps of: a) preparing a wafer having a plurality of image sensors and connection pads; b) coating a surface of the wafer where the image sensors are formed with an adhesive; c) attaching a transparent plate; d) patterning the transparent plate; and e) dicing the wafer.

Preferably, the method further includes a step of: f) forming connectors on the connection pads following step d).

Preferably, the method further includes a step of: g) grinding the upper surface of the transparent plate and the lower surface of the wafer.

In accordance with yet another aspect, the present invention provides a method for fabricating a solid state imaging device, which includes the steps of: a) providing a wafer having a plurality of image sensors and connection pads; b) coating a surface of the wafer with an adhesive; c) attaching a transparent plate; d) patterning the transparent plate; e) forming connectors on the connection pads; f): dicing the wafer; g) mounting the connectors on one side of the main board; and h) mounting a lens housing having a lens on the other side of a main board.

### BRIEF DESCRIPTION OF THE DRAWINGS

The above aspects and features of the present invention will be more apparent by describing certain embodiments of the present invention with reference to the accompanying drawings, in which:

FIG. 1 is a cross-sectional view showing a prior art image sensor package;

FIG. 2 is a cross-sectional view illustrating an image sensor package in accordance with an embodiment of the present invention;

FIG. 3 is a cross-sectional view depicting a solid state imaging device in accordance with an embodiment of the present invention; and

FIGS. 4A to 4G are cross-sectional views illustrating a method for fabricating an image sensor package and a solid state imaging device in accordance with an embodiment of the present invention.

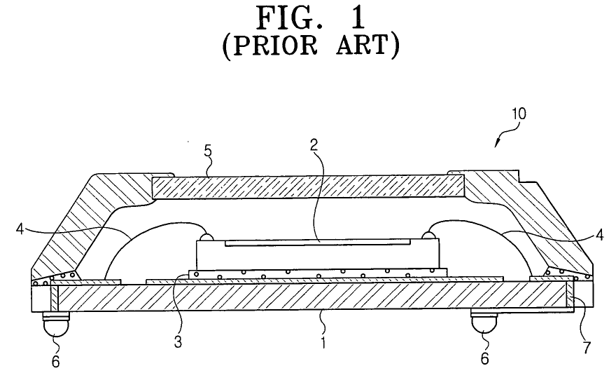

### DETAILED DESCRIPTION OF THE EXEMPLARY EMBODIMENTS

Certain embodiments of the present invention will next be described in greater detail with reference to the accompanying drawings. However, the present invention should not be construed as being limited thereto.

In the following description, the same drawing reference numerals are used to depict the same elements in the various drawings. The subject matter including a detailed construction and elements defined herein are provided to assist in a comprehensive understanding of the invention, and it is to be understood that the present invention can be carried out in other ways. Also, well-known functions or constructions are not described in detail since they would obscure the invention in unnecessary detail.

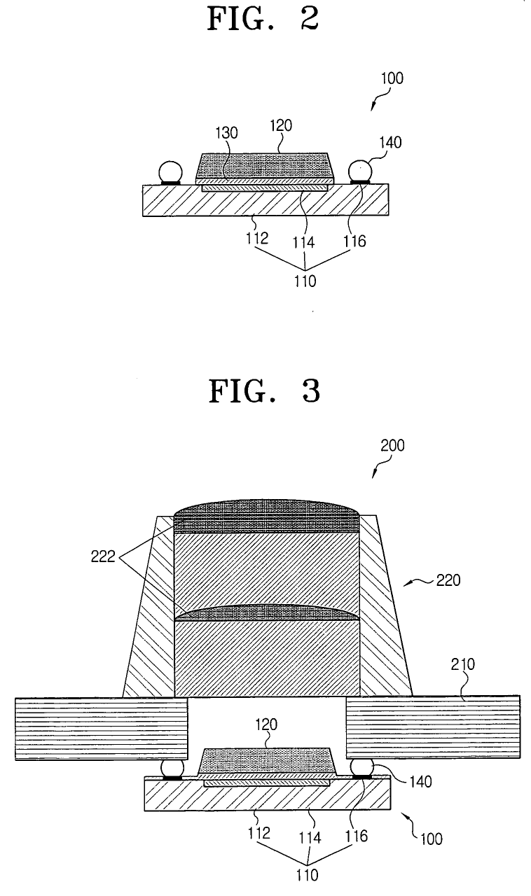

Referring to FIG. 2, an image sensor package 100 includes an image sensor chip 110, a transparent plate 120, and a connector 140.

The image sensor chip 110 is provided with an image sensor 114 and a connection pad 116. As for the image sensor 114, a photoelectric transforming device such as a photodiode may be used. The image sensor may be of several types such as a Charge-Coupled Device (CCD), a Complementary Metal Oxide Semiconductor (CMOS), and the like. Metal wires (not shown) connected to the connection pads 116 are formed on an activated surface of the image sensor 114. Preferably, the connection pads 116 are formed of a material having a high conductivity, such as gold.

The transparent plate 120 is attached to the upper surface of the image sensor 114 via adhesive 130. The transparent plate 120 is formed of transparent glass, a transparent resin, or a light-transmitting ceramic. The transparent plate 120 protects the image sensor 114 from the outside.

One side of the connector 140 is formed on the connection pad 116 and the other side is connected to an external terminal. In the present embodiment, a bump is utilized as the connector 140. As for the bump 140, a solder bump using a solder ball or a gold bump containing gold (Au) is used. The bump electrically connects the image sensor package to an external terminal, i.e., a main board 210 (see FIG. 3) for exchange of signals. Thus, the bump 140 performs a first role of a terminal for transmitting signals from the image sensor chip 110, and a second role of a joint for connecting the image sensor chip 110 to the main board 210. Although not illustrated in the drawings, the bump 140 can be formed as a Ball Grid Array (BGA) type or a Land Grid Array (LGA) type by forming a land region on top of the image sensor chip 110.

Meanwhile, the image sensor package 100 in this embodiment of the present invention is connected to the main board 210 through the solder bump 140. However, the present invention is not limited thereto and various methods can be used for the connection as long as such method can electrically connect the image sensor package 100 to the main board 210.

For example, an anisotropic conductive film (ACF), anisotropic conductive paste (ACP), or screen printing can be used as the connector.

Although not shown in the drawings, the image sensor chip 110 can include an underfill for protecting the image sensor chip 110, except the connector 140.

FIG. 3 is a cross-sectional view depicting part of a solid image device 200 using the image sensor package 100 of FIG. 2 in accordance with an embodiment of the present invention.

As shown, the solid image device 200 includes the image sensor package 100 connected to one side of the main board 210 through the bump 140 and includes a lens housing 220 on the other side of the main board 210. A lens 222 is set up in the lens housing 220. Also, a pad (not shown) can be set up in one side of the main board 210 connected to the bump 140. Meanwhile, the main board 210 may utilize a rigid printed circuit board (PCB) or a flexible PCB.

According to the above structure, image signals of light passing through the lens 222 and the transparent plate 120 are transformed into electrical signals in the image sensor chip 110. The electrical signals thus obtained are transmitted to the main board 210 through the connection pad 116 and the bump 140.

As described above, a conventional image sensor package can transmit signals, in that the image sensor chip is electrically connected to an additional chip substrate and the chip substrate is electrically connected to the main board through a connector such as the bump. However, the image sensor package of the present invention does not require and preferably does not contain a chip substrate connected to the image sensor chip, but rather has a simple structure in that the image sensor chip is directly connected to the main board electrically through the connector. Therefore, an interconnection process and thinning process of the image sensor package are simplified.

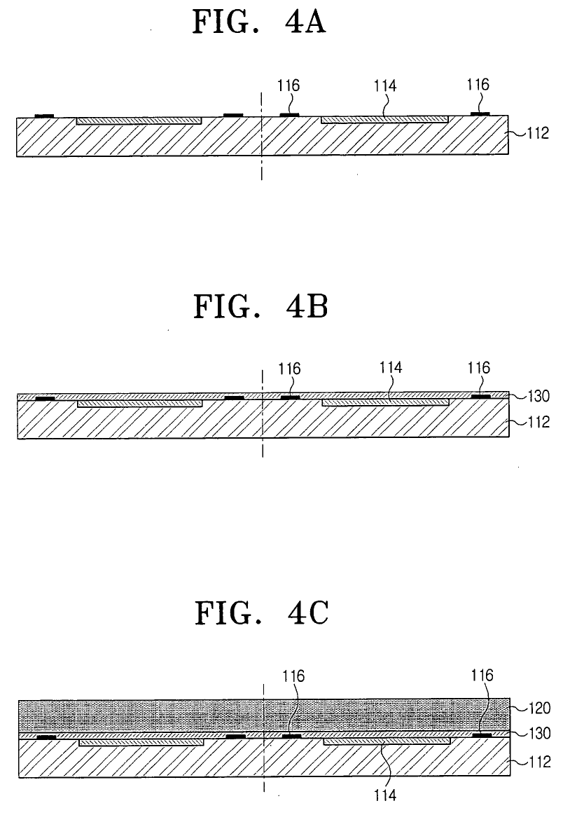

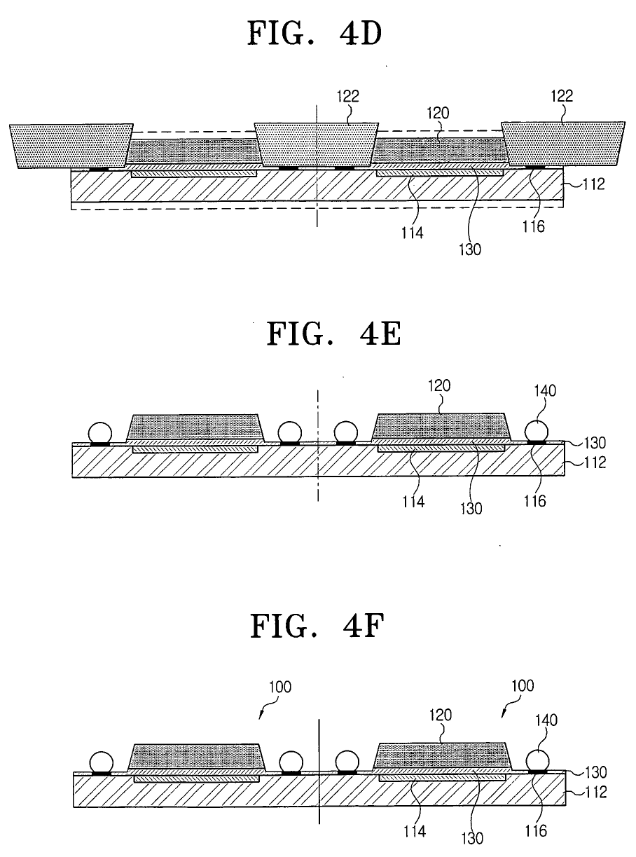

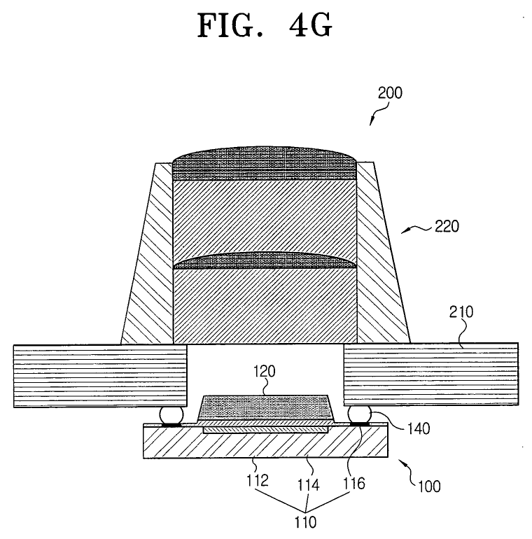

Hereafter, an image sensor package and a fabrication method of a solid state imaging device will be described in accordance with an embodiment of the present invention, referring to FIGS. 4A to 4G. As illustrated, the image sensor package 100 in this embodiment of the present invention is fabricated by forming a plurality of image sensor chips on a wafer. As shown with dotted lines, the same process is performed on each image sensor chip.

With reference to FIGS. 4A and 4B, a semiconductor wafer 112 with a plurality of image sensors 114 and connection pads 116 formed thereon is prepared. Then, an adhesive 130 is applied to the upper surface of the wafer 112 with the image sensors 114 thereon. Subsequently, a transparent plate 120 is placed onto the adhesive 130, as shown in FIG. 4C.

As shown in FIG. 4D, the upper surface of the transparent plate 120 and the lower surface of the wafer 112 are dry etched or grinded to thereby reduce their respective thicknesses. Generally, the thickness of a wafer 112 is about 300 μm, but it is preferable to etch or grind the wafer to a thickness of 50 to 100 μm. As such, a thin image sensor package can be fabricated. Subsequently, a predetermined area of the transparent plate 120, which is the area 122 between adjacent image sensors 114, is wet-etched and the transparent plate 120 is patterned. The patterning exposes the connection pads 116 to the outside.

Subsequently, bumps 140 are formed on the connection pads 116 by disposing bumps on the connection pads 116 and attaching the bumps thereto by heat compression. After the bumps 140 are formed, the wafer 112 is diced and individualized on a basis of an image sensor chip 110, which is shown in a solid line of FIG. 4F. The image sensor package 100 of the present invention is thus completed.

Subsequently, as shown in FIG. 4G, the image sensor chip 110 is electrically connected to the main board 210 by forming the bumps 140 on the main board 210 through heat compression. The bumps 140 are originally 80 to 100 μm high but the height is reduced by about 30 μm after the heat compression. Meanwhile, the DCA process where the image sensor chip 110 is directly attached to the main board 210 can be carried out using a conventional semiconductor packaging process without particular limitations. Then, the lens housing 220 is formed on the main board 210.

As described above, in the image sensor package and the solid state imaging device of the present invention, the image sensor chip is directly connected to the main board of the solid image device without an additional substrate for electrical connection. Also, the devices of the present invention can be realized in a chip-size package (CSP) having a size almost the same as the image sensor chip by using wafer-level packaging and performing a direct chip attachment (DCA) on the main board without wire bonding on the image sensor chip. Therefore, it is possible to fabricate a small and thin image sensor package and solid state imaging device using the image sensor package. The technology of the present invention can make use of conventional packaging processes without particular limitation. Furthermore, since the number of interconnection processing steps is decreased remarkably, the production cost can be reduced.

The foregoing embodiment and advantages are merely exemplary and are not to be construed as limiting the present invention. The present teachings can be readily applied to other types of apparatuses. Also, the description of the embodiments of the present invention is intended to be illustrative, and not to limit the scope of the claims, and many alternatives, modifications, and variations will be apparent to those skilled in the art.

What is claimed is:

1. An image sensor package which is electrically connected to a main board of a solid image device for exchange of signals, comprising:
an image sensor chip having an image sensor and a connection pad;
a transparent plate attached to the image sensor chip; and
a connector, one side of which is connected to the connection pad and the other side of which is connected to the main board.

2. The image sensor package as claimed in claim 1, wherein the connector comprises any of a bump, an anisotropic conductive film (ACF), an anisotropic conductive paste (ACP), and a screen printing.

3. The image sensor package as claimed in claim 2, wherein the bump is a solder bump or a gold-containing bump.

4. The image sensor package as claimed in claim 1, wherein the connection pad is made of gold.

5. A solid state imaging device, comprising:
a main board;
an image sensor chip having an image sensor and a connection pad;
a transparent plate attached to the image sensor chip;
a connector, one side of which is connected to the connection pad and the other side of which is connected to the main board; and
a lens housing mounted on a side of the main board opposite the connector.

6. The solid state imaging device as claimed in claim 5, wherein the connector comprises any of a bump, an anisotropic conductive film (ACF), an anisotropic conductive paste (ACP), and a screen printing.

7. The solid state imaging device as claimed in claim 6, wherein the bump comprises a solder bump or a gold-containing bump.

8. The solid state imaging device as claimed in claim 5, wherein the main board is a rigid printed circuit board or a flexible printed circuit board.

9. A method for fabricating an image sensor package, which comprises:
a) providing a wafer having a plurality of image sensors and connection pads;
b) coating a surface of the wafer where the image sensors are formed with an adhesive;
c) attaching a transparent plate;
d) patterning the transparent plate; and
e) dicing the wafer.

10. The method as claimed in claim 9, which further includes:
f) forming connectors on the connection pads after the step d).

11. The method as claimed in claim 10, which further includes:
g) grinding the upper surface of the transparent plate and the lower surface of the wafer.

12. A method for fabricating a solid state imaging device, which comprises:
a) providing a wafer having a plurality of image sensors and connection pads;
b) coating a surface of the wafer with an adhesive;
c) attaching a transparent plate, d) patterning the transparent plate;
e) forming connectors on the connection pads;
f) dicing the wafer;
g) mounting the connectors on one side of the main board; and
h) mounting a lens housing having a lens on the other side of the main board.

13. The method as claimed in claim 12, which further comprises:
i) grinding the upper surface of the transparent plate and the lower surface of the wafer.
